(19) United States
(12) Patent Application Publication
(10) Pub. No.: US 2006/0019411 A1
(43) Pub. Date: Jan. 26, 2006

(54) Storage container for receiving precision substrates such as wafers

(75) Inventors: Shigeaki Ueda, Osaka (JP); Yasuyuki Watanabe, Yamaguchi (JP)

Correspondence Address: JUDGE PATENT FIRM;RIVIERE SHUKUGAWA 3RD FL., 3-1 WAKAMATSU-CHO, NISHINOMIYA-SHI, HYOGO, 662-0035, JP

(73) Assignees: Kabushiki Kaisha Daihachikasei, Higashiosaka-shi, Osaka (JP); Pla-Net Corp., Tokyo (JP)

(21) Appl. No.: 10/531,304

(22) PCT Filed: Oct. 15, 2003
(86) PCT No.: PCT/JP03/13236

§ 371 Date: Apr. 14, 2005

(30) Foreign Application Priority Data
Oct. 17, 2002 (JP) 2002-302921

(51) Int. Cl. H01L 21/00

(52) U.S. Cl. 438/1

(57) ABSTRACT

A storage container for receiving precision substrates such as wafers, having increased strength and improved drying ability when washed. The storage container has a letter L-shaped circumferential wall (12) projectingly provided on an outer wall face, the circumferential wall functioning as a gasket insertion groove (12a). A first flange (13) horizontally extending from the lower end face of the letter L-shaped circumferential wall (12) and a second flange (14) horizontally extending from a position 10-30 mm lower than the first flange are respectively formed integrally with the container. Vertical ribs (15) are formed between the lower face of the first flange (13) and the upper face of the second flange (14).

### Technical Field

This invention relates to a container for storing a plurality of precision-requiring substrate plates (hereinafter termed substrate plates) including semiconductor wafers under conditions such that the plurality of substrate plates are singly placed without contacting and substantially equally spaced from each other, and are placed to be convenient for handling, storing, transferring, washing, etching, drying or the like.

### BACKGROUND ART

A substrate-plate storage container for usage such as for storing, transportation, washing, etching or drying, comprises typically a cassette which contains a plurality of substrate plates in a state in which they are substantially equally spaced from each other, a cassette lid which immobilizes the stored plates by pressing them from above, a container body which includes the lid and will contain the cassette inside, a gasket which is fitted in a rim around the container body opening, and a container lid. (See FIG. 1)

Principally this sort of container is required to have high level cleanliness, since substrate plates including semiconductor wafers will be qualitatively damaged by microscopic dust or dirt becoming attached to them, for which requirement every component of a container is subjected to pre-washing prior to the storing of substrate plates. Therein, each container body is swiveled in inverted status or such a status as appropriate to washing work, alternatively each body is hung up to receive jet water flows while a washing tool may move up and down. Then, each body is subjected to drying for drainage of remaining water.

Meanwhile, such containers for semiconductor wafers have been required to have an airtight seal durable to various sorts of transportation, so that attempts have been made to reinforce the strength of the container bodies in the prior art. Specifically as shown in FIG. 6, a number of ribs and curved portions have been introduced in designing a container body 21. Further, in order for manual handling to be convenient, typically an upward channel 22a to engage with a gasket has been provided heightwise at a position slightly below an upper opening 22, and yet further a flange 23 which rims out from a body sidewall to turn down (or sectionally like an inverted L) has been provided for on the whole or a portion of the periphery. Essentially these attempts have been intended to contribute to easier engagement with a carrying person's fingers and enhancement of the strength around the upper opening. However, as will be noted later, difficulties with such a flange in the turned-down form remain in washing followed by drying.

To continue the description, after washing by water spray, the container body is dried in inverted status, wherein the container is left to stand so that water remaining in recesses in the container body will drain, wherein the turndown shaped flange 23 in FIG. 6 turns into channel or sump to cause difficulty for drying by air blow, that is, the shape of the flange turndown makes hindrance for air to reach every surface area, with the result that efficient water removal is not attained.

A plastic, which is the material of the container body, easily takes on static charges which attract dust or dirt in air to mix with water and then to leave contamination or spots on the body surface after the drying. Thus, container bodies are demanded to be free of such a trouble.

In order to prevent the stay of washing water, various structures that should be added to a substrate plate container have been proposed in prior art. For example, the reference 1 noted below discloses the provision of a through hole or slit in the down-turned flange noted above. The reference 2 noted below discloses the provision of overlying rims wherein a first rim, being integrally formed at an end of a flange which extends upward from about an upper mouth of the container body, projects outwardly with slight tapering so that its upper surface will be slightly inclined as decreasing in thickness with concomitant effect to its back surface, in order for staying water to slide laterally, and wherein a second rim, located lower heightwise, is provided with a similar inclined angle.

The reference 1: Japanese Patent Published Application 1999-297807, claim 1 and FIG. 6

The reference 2: Japanese Patent Published Application 2002-110775, Specification Page 3.

### DISCLOSURE OF INVENTION

Assuming a typical process of washing followed by drying of container bodies, the body in reference 1 (See FIG. 6) relieves the sump action of the flange by a through hole created to promote the drainage of remaining water. But the reference 1 art does not permit the drying air to flow into a space inside the flange with minimal dead-angle shadowing. Instead, this art has to wait for such water to flow out in the left-to-stand drainage. In other words, this art does not provide such clever structures that flange-related areas will be fully exposed to the drying air flow. In the case of the reference 2 art (See FIG. 7), though the drying air which normally flows in lateral directions is not largely hindered, the creation of a further reinforcing rib to interconnect between the first and second rims with minimal dead-angle shadowing to air flows is rendered to be very difficult, resulting in leaving weakness in the structural strength in vertical direction heightwise at the ribs.

Substrate plate containers are often transported abroad by air freight, wherein on the ground or under atmospheric air pressure the plates are stored under a tight seal with the aid of the gasket and the container lid, and then taken to be on board or loaded in a cargo room of an air service plane. Then, the plane takes off and flies up to a high altitude, air pressure in the cargo room reduces. Now, air pressure unbalance or difference between outside the container and inside thereof develops to such an extent that the lid and the container body will deform so as to break the seal between the lid and the body, or at the same time, a body sidewall will swell outward, yielding a deformation that affects the upper opening. Then, a landing of the plane will reinstate the air pressure environmental to the containers wherein the reverse deformation attracts air from outside the container, by which dust or dirt will be introduced into the container, resulting in contamination to stored substrate plates. Improvement of structural strength for the substrate containers is demanded from such experience as noted, specially for the need of high level durability against changes in air pressure.

As noted before, in the drying step of the washing process, pressure air is applied to blow off remaining water staying in recessed areas. Although general consideration assumes it clever to allow water droplets to move on inclined surfaces, but in an industrial drying process, blowing off by power of pressure air is by far efficient. Thereby desired is a configuration to dispense with shapes which leave dead-angle shadowed areas unexposed to oncoming air flows.

A task for the present invention to achieve lies in a configurative design which will provide a substrate plate container with sufficient structural strength as well as excellent drainage by air blow.

The present invention provides: A container structured of a container body (10), a container lid (2), a cassette (4), and a cassette lid (3) to house said cassette (3) in air tight condition and to store a plurality of precision-requiring substrate plates including semiconductor wafers placed in said cassette (3) in substantially equally spaced status:
said container body (10) is provided with a sectionally L shaped flange (12) surrounding an external sidewall of said container body (10) outer-peripherally to form an upward channel (12a) so as to receive a gasket (5) heightwise at a position below from an upper opening periphery for a height of the gasket (5);
said container body (10) is further provided with a first flange (13) rimming out integrally from a bottom of the L shaped flange (12) to surround laterally said body (10), with exception for a prescribed length (or D zone) located at centers on front and rear of the body (10);
said container body (10) is further provided with a second flange (14) rimming out from the external sidewall of said body (10), with a shape and rim-out length substantially equal to the first flange (13), at a position heightwise one to several centimeters below from the first flange (14), with exception for the prescribed length (or D zone); the first flange (13) and the second flange (14) being interconnected with a plurality of vertical ribs (15);
said container body (10) is further provided with, within the prescribed length (D), at least one D zone lateral rib (16) rimming out from the front and rear sidewalls of the body (10) for a length substantially equal to the L shaped flange (12), at a position heightwise above from the second flange (14); the D zone lateral rib (16) each being provided with at least one engaging projection (16a) engageable with said container lid (2) to accomplish air tight seal; the L shaped flange (12) and the D zone lateral rib (16) being interconnected with a plurality of D zone vertical ribs (17).

Thereby the reinforcement for structural strength on the upper opening periphery of the container body (10) being accomplished.

The container as noted above, wherein an underside of the L shaped flange (12) forming a channel (12a) to receive the gasket (5), and undersides of the first and second flanges (13, 14) are provided outwardly with an elevation angle (θ1), and uppersides of the first and second flanges (13, 14) are provided outwardly with a depression angle (θ2). Thereby water remaining on undersides of the first and the second flanges is promoted to drainage.

The container as noted above, wherein the second flange (14) and the D zone lateral rib (16) are, each at an outer edge, turned down to form a lateral tab (14a, 16a), the lateral tabs (14a, 16a) each including a cut point (14b, 16c) at an intermediate point thereof. Thereby reinforcement, avoidance of possible hand slips, and drainage are enhanced.

The container as noted above, wherein a plurality of vertical ribs (15) and D zone vertical ribs (17) are installed with a lateral interval from 0.5 to 3.5 times a vertical interval between the first and second flanges (13, 14)(or aspect ratio: lateral/vertical), or a vertical interval between the L shaped flange (12) and the D zone lateral rib (16). Thereby efficiency in drainage by blow of pressure air is promoted.

In comparison of the inventive container with prior art one, the inventive container comprises the lateral reinforcement by the L shaped flange 12 (the first flange 13) and the second flange 14, and the same by parts of the L shaped flange 12 and the D zone lateral rib 16. Further a plurality of vertical ribs 15 and D zone vertical ribs 17 additionally installed. Thereby improved stiffness is attained on the upper opening wall 11 to resist sufficiently pressure differences during transportation, dispensing with the installation of a multiplicity of flanges on prior art ones.

As noted above, the inventive container features in installation of a plurality of vertical and lateral ribs on its sidewall, that is, an upper portion of the sidewall of the body is divided into a plurality of square profiled sections or square open pockets. This profile has possible inconvenience in drainage, but the air blow in lateral directions is usually adopted for drying, and it has been experimentally proved that the drying is not inconvenienced as far as minimal dead angled shadow is shaped, and this principle is achieved by the inventive container.

Mentioning a pattern example, where a vertical interval between the first and the second flanges ranges 1.5 to 3.0 centimeter, an aspect ratio (ratio of lateral interval/vertical interval) of 3.5 to 0.5 is acceptable, since good performance in drainage has been found. Otherwise some difficulty in drainage has been found.

### BRIEF DESCRIPTION OF DRAWINGS

FIG. 1 shows an exploded perspective view of a substrate plate container embodiment of the present invention for illustration of components which partake the inventive embodiment.

FIG. 2 shows a perspective view of a body of the substrate plate container embodiment.

FIG. 3 shows a front view of the body of the substrate plate container embodiment, wherein a left half portion of a center line is an external view and a right half portion of the same is a sectional view.

FIG. 4 shows a vertically sectioned partial view of the body including a gasket insert channel (12a), a first flange (13), and a second flange (14).

FIG. 5 shows a half-sectioned bottom view of the container body for illustration of a prescribed length located at center (D) and a D zone lateral rib (16) fabricated at a front and a rear side thereof.

FIG. 6 shows a prior art substrate plate container embodiment, wherein FIG. 6 (a) is a perspective view and FIG. 6(b) is a partially sectioned view according to an A-A view line in FIG. 6(a).

FIG. 7 shows another prior art substrate plate container embodiment, wherein FIG. 7 (a) is a front view and FIG. 7(b) is a sectional side view enlarged from a portion encircled in FIG. 7 (a).

### MODES FOR CARRYING OUT THE INVENTION

Embodiments will be detailed for carrying out an inventive substrate plate container 1 to store semiconductor wafers and the like.

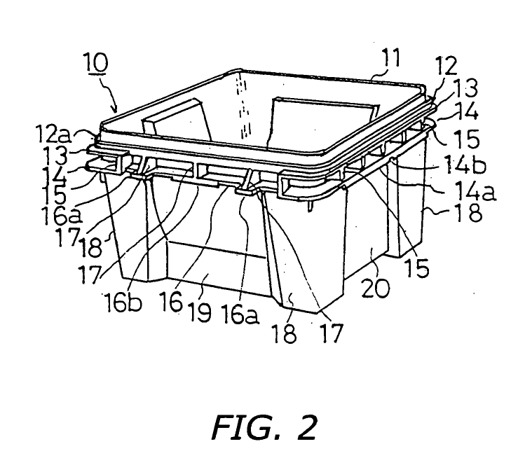

Referring to a container body 10 to be produced by a plastic molding, its upper opening edge defines a container opening wall 11 designed to engage with a lid 2, and at a position on an external surface of the opening wall 11 and heightwise a slight below from the upper edge, a sectionally L letter shaped flange 12 rims out forming an outer peripheral wall. Thereby a peripheral gap between the wall 11 and the L letter flange (or outer peripheral wall) 12 form a channel 12a for insertion of a gasket 5 (will be referred to later). And outwardly of an outer edge of the L letter flange 12, a first flange 13 rims out farther in integral formation with the bottom plate of the L letter flange 12. (Therefore, the bottom plate of the L letter flange 12 is considered to be a part of the L letter flange 12 and at the same time is considered to be a part of the first flange 13 and accordingly two characters 12 and 13 are awarded to the same location.) Then, the first flange 13 surrounds the body 10 laterally excepting a prescribed length D (or D zone) at two centers on front and rear of the body 10. In addition, heightwise at a position below such as one to several centimeters (or spaced for an appropriate length) from the first flange 13, provided is a second flange 14 having a shape or a rim-out length substantially equal to the first flange 13. In connection therewith a plurality of vertical ribs 15 are provided to interconnect between the first flange 13 and the second flange 14, wherein a lateral interval between two adjacent vertical ribs 15 assumes to take 0.5 to 3.5 times the vertical interval between the first flange 13 and the second flange 14, preferably to take one to two times. (See FIG. 2)

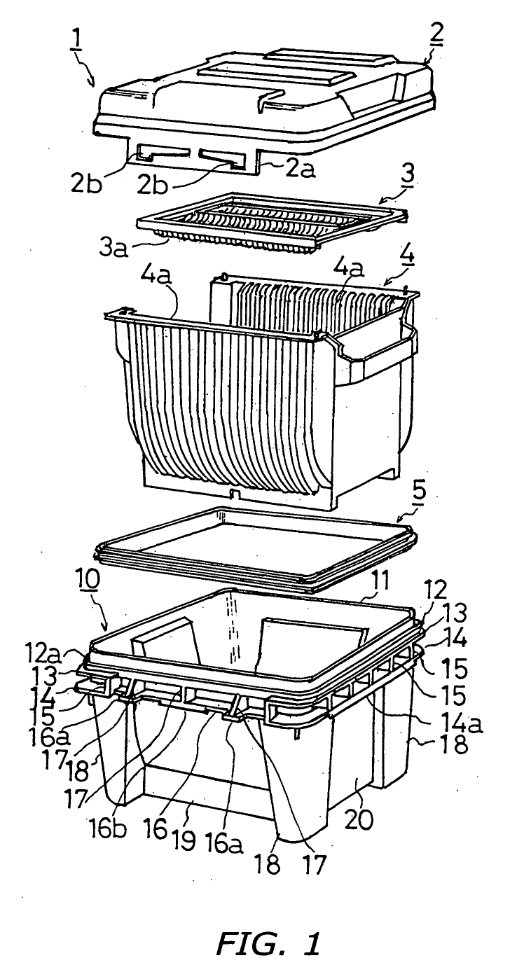

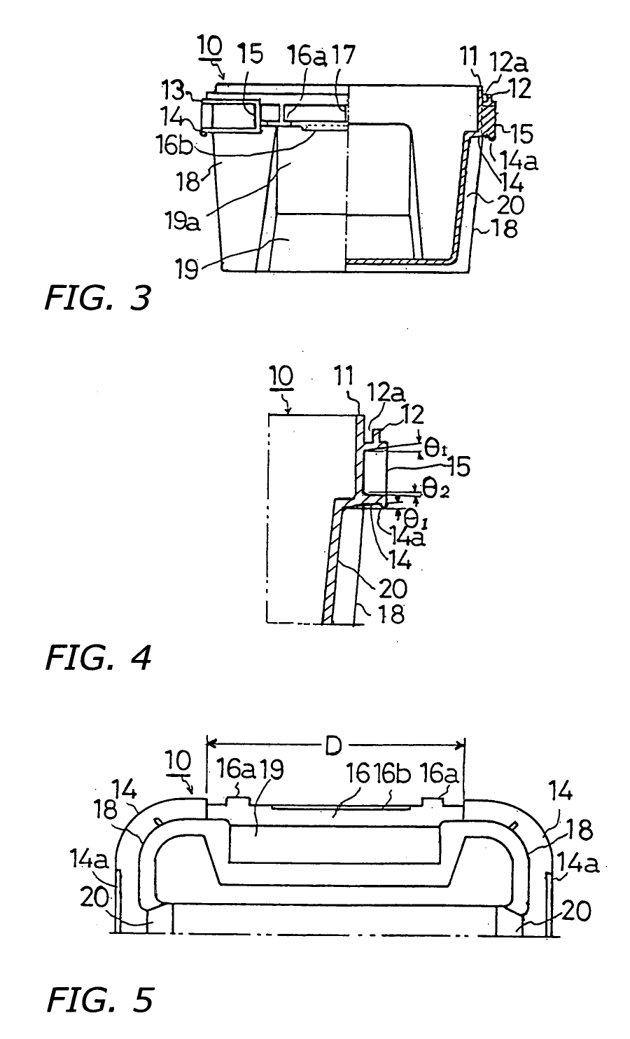

The prescribed length D (or D zone) at two centers on front and rear of the body 10 is available to allow engagement between the lid 2 and the container body 10. That is, the lid 2 is provided with a pair of engaging plates 2a which extend downwardly from a peripheral edge of the lid 2. (See FIG. 1, wherein the engaging plate 2a provided on the front side is seen) And the engaging plate 2a is pierced with a pair of engaging holes 2b for engagement with a mechanism provided on the body 10 as will be noted in the following. The mechanism provided on the body 10 extending for the length D includes a D zone lateral rib 16 provided with a pair of engaging projections 16a, a pair of lateral tabs 16b, and a dividing point 16c, wherein the D zone lateral rib 16 has a rim-out length comparable to the L shaped flange 12 and is positioned at a height level which is lower than the L shaped flange 12, yet slightly higher than the second flange 14, (see FIGS. 2 and 3) and then a plurality of D zone vertical ribs 17 interconnect the L shaped flange 12 and the D zone lateral rib 16, wherein the lateral interval between two adjacent D zone vertical ribs 17 is made to be 0.5 to 3.5 times the vertical interval between the L shaped flange 12 and the second flange 14 (or aspect ratio of lateral/vertical), preferably to be one to two times. (See FIG. 2) To continue the description, the D zone lateral rib 16 is at its edge turned down to form the lateral tab 16b having a width somewhat shorter than the D length and a height about one to two millimeters, and the D zone vertical ribs 17 each form a slanted brace extending downwardly to the upper surface edge of the engaging projection 16a for reinforcement.

Referring to the L letter flange 12 (the first flange 13), the second flange 14, the vertical rib 15, the D zone lateral rib 16, and the D zone vertical rib 17, each of which is provided, at its connection point with the wall of the container body 10, with a radius of a fillet curve, said radius being a bit less than half the body wall thickness, wherein a tapering is defined outwardly to be thinner commensurate with a length from the connection point. The curve as depression angle θ1 and elevation angle θ2 illustrated in FIG. 4 assumes to take a value of 1° to 5° which has been known as a draft angle in the plastic injection molding technology. In the case of the L letter flange 12 (the first flange 13), the second flange 14, and the D zone lateral rib 16, it is preferable for θ1 to be somewhat larger than θ2 in order to promote drainage of remained water in allow-to-stand status. (See FIG. 4)

It is possible that the provision of the elevation angle (θ2) on the underside of the second flange 14 causes slips in manual handling, for which cause the second flange 14 is, at its outer edge, turned down to form the lateral tab 14a. Further, in order to solve this possible trouble yet to keep good drainage of remained water, a cut point 14b is provided at an intermediate point of the length of the lateral tab 14a. (See FIG. 2)

Now, structural features will be described on points other than those described above. The container body 10 has four corner columns 18 for a height length under the second flanges 14, and an upper portion of the front or rear sidewall between two columns 18 is formed to be a curved part (or sidewall) 19a whose under edge recedes into the body 10, and two sidewalls at right and left form vertical flat planes with a slight recess to connect with a bottom plate of the body 10. These structural designs contribute to reinforce stiffness of the whole body. Referring to the lid 2, it has two engaging plates 2a at front and rear centers so as to match the D zone, as noted before, and the plates 2a each are integrally formed with turndown and are pierced with a pair of the engaging holes 2b, as also noted before.

Turning to a cassette 4 for the storage of substrate plates, (See FIG. 1) it is generally a square vessel having an open upper opening and its front and rear walls forming vertically a round bottom, wherein a number of separating walls are projected inwardly from the walls so that substrate plates may be inserted singly into a groove 4a formed between two adjacent groove walls. Referring to a cassette lid 3, it is designed to immobilize (or press on) the plates inserted into the grooves 4a, for which purposes a number of arms 3a are arranged to span between opposite frames of the lid 3 at the same pitch as that between adjacent grooves 4a so as for an arm 3a to press on a substrate plate.

Prior to use, a substrate plate container 1 is normally pre-washed by a washer equipped with a water spreader and an air dryer, wherein a plurality of the containers 1 are swiveled or hung up in inverted or nearly inverted status, that is, each container is retained with its upper opening faced downward and washing water is jetted or sprayed, and then for drying, pressure air is jetted or spread to blow off remaining water. Referring to merits with the containers 1 of the present invention, the first flange 13, the second flange 14, the vertical ribs 15, and their related structures having squares defined by two dimensions in profile are provided to reinforce the strength of the body's upper opening wall. Such structures are generally considered to become a sump, however, as mentioned above, such structures are improved so that the remaining water will be readily blown off.

Next, how to use a container 1 of the present invention will be explained with reference to FIG. 1. At start, a container body 10 is, at its upper opening, fitted with a gasket 5, and a cassette 4 which was packed with substrate plates, not shown, is brought or placed into the container body 10. Then, a cassette lid 3 with an elastic presser 3a set in place is put on the top of the cassette 4 followed by capping of a lid 2 and fitting of engaging plates 2a with engaging projections 16a for tight seal.

The containers of the present invention bring forth remarkable merits in particular in the process of washing followed by drying such containers, that is, in such process the container bodies are kept to be inverted status, wherein the first flange 13, second flange 14 and, D zone lateral ribs 16 are free of sump action, instead, these squares defined by two dimensions in profile are at the ready to shed off remaining water. Resultantly, minimal attachment with dust or dirt during the drying.

The inventive substrate plate containers 1 are provided with remarkably upgraded structural strength which the L shaped flange 12, first flange 13, second flange 14, D zone lateral ribs 16, the vertical ribs 15, and the D zone vertical ribs 17 have mainly brought forth, so that resolution is awarded to the problem of container breakage due to difference in air pressures taking place during air shipments.

In this invention, the body 10 includes the second flange 14, wherein the flange 14 is provided with the lateral tab 14a including the notch 14b, so that drainage of remaining water is promoted and at the same time, the trouble of manual hand slips is resolved.

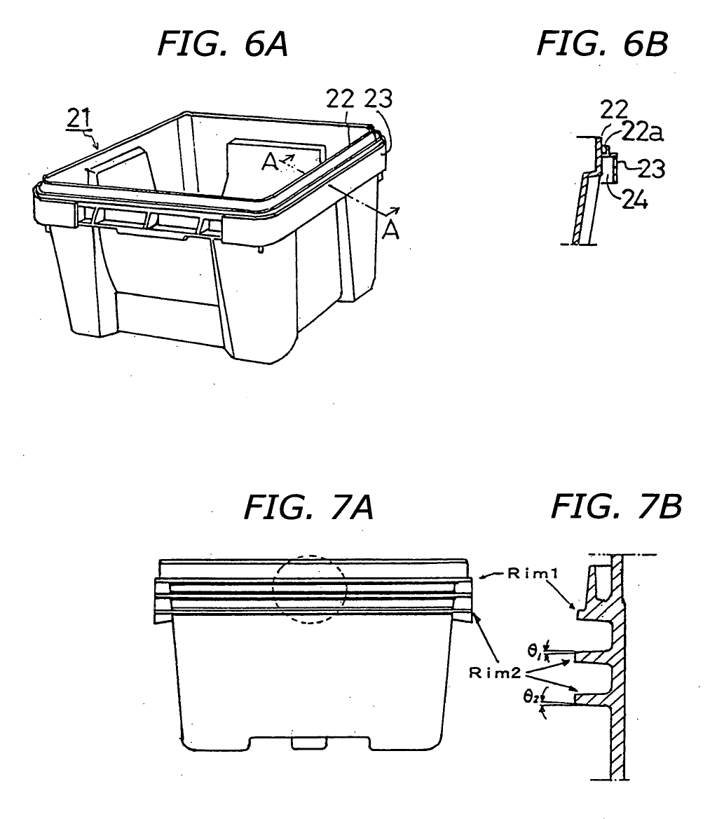

Mentioning a prior art container shown in FIG. 6, it was customary for a carrying person to take or bring up the container box by attaching the palm of his hand onto the external surface of the flange 23 together with insertion of the fingers into the downward groove 24 which was formed inside the flange 23, wherein the turndown edge of the flange 24 was so convenient to hand engagement that the carrying person often brought up the box to carry by the use of a single hand, by which access the contents, substrate plates, were largely tilted or shaken inside, with the result that the substrate plates suffered from damage or breakage. In contrast, the inventive containers are designed for a carrying person to be unable to bring up the container with one hand alone to make engagement with one of a plurality of lateral flanges mounted on one sidewall. Instead, he must use two hands to attach on two sidewalls 20 in order to grip the bottom corners thereof. Thus, he is required to pay considerable attention in handling and thereby deliberate or safe handling is realized.

1. A container comprising a container body (10), a container lid (2), a cassette (4), and a cassette lid (3) to house said cassette (3) in air tight condition and to store a plurality of precision-requiring substrate plates including semiconductor wafers placed in said cassette (3) in substantially equally spaced status:
said container body (10) including a sectionally L shaped flange (12) surrounding an external sidewall of said container body (10) outer peripherally to form an upward channel (12a) so as to receive a gasket (5);
said container body (10) further including a first flange (13) rimming out integrally from a bottom of the L shaped flange (12) to surround laterally said body (10), with exception for a prescribed length (D) located at centers on front and rear of the body (10);
said container body (10) further including a second flange (14) rimming out from the external sidewall of said body (10), with a shape and rim-out length substantially equal to the first flange (13), at a position heightwise one to several centimeters below from the first flange (14), with exception for the prescribed length (D); the first flange (13) and the second flange (14) being interconnected with a plurality of vertical ribs (15);
said container body (10) further including, within the prescribed length (D), at least one D zone lateral rib (16) rimming out from the front and rear sidewalls of the body (10) for a length substantially equal to the L shaped flange (12), at a position heightwise above from the second flange (14); the D zone lateral rib (16) each being provided with at least one engaging projection (16a) engageable with said container lid (2) to accomplish air tight seal; the L shaped flange (12) and the D zone lateral rib (16) being interconnected with a plurality of D zone vertical ribs (17).

2. The container as defined in claim 1, wherein an underside of the L shaped flange (12) forming a channel (12a) to receive the gasket (5), and undersides of the first and second flanges (13, 14) are provided outwardly with an elevation angle (θ1), and uppersides of the first and second flanges (13, 14) are provided outwardly with a depression angle (θ2).

3. The container as defined in claim 1, wherein the second flange (14) and the D zone lateral rib (16) are, each at an outer edge, turned down to form a lateral tab (14a, 16a), the lateral tabs (14a, 16a) each including a cut point (14b, 16c) at an intermediate point thereof.

4. The container as defined in claim 1, wherein a plurality of vertical ribs (15) and D zone vertical ribs (17) are installed with a lateral interval from 0.5 to 3.5 times a vertical interval between the first and second flanges (13, 14), or a vertical interval between the L shaped flange (12) and the D zone lateral rib (16).
